(19) United States
(12) Patent Application Publication
(10) Pub. No.: US 2023/0380121 A1
(43) Pub. Date: Nov. 23, 2023

(54) ELECTRICALLY CONDUCTIVE FILLERS WITH IMPROVED CORROSION RESISTANCE

(71) Applicant: OERLIKON METCO (US) INC., Westbury, NY (US)

(72) Inventor: Alex IASNIKOV, St. Albert, AB (CA)

(73) Assignee: OERLIKON METCO (US) INC., Westbury, NY (US)

(21) Appl. No.: 18/027,533

(22) PCT Filed: Dec. 3, 2021
(86) PCT No.: PCT/US2021/061833

§ 371 Date: Mar. 21, 2023

Related U.S. Application Data
(60) Provisional application No. 63/121,049, filed on Dec. 3, 2020.

(51) Int. Cl. H05K 9/00

(52) U.S. Cl. CPC H05K 9/0083

(57) ABSTRACT

An electrically conductive composite powder having improved corrosion resistance is provided for microwave shielding applications. The electrically conductive composite powder composition includes a core of particles having a low density and a high dielectric constant; a nickel layer that is coated onto the core of particles; and a corrosion resistant alloy layer that is deposited onto the nickel layer. The electrically conductive composite powder exhibits excellent corrosion resistance performance, while also being substantially lower in cost that conventional Ag/glass shields. The electrically conductive composite powder can be used across a broad frequency range.

This application claims priority to U.S. Provisional Application No. 63/121,049, filed Dec. 3, 2020, the disclosure of which is hereby incorporated by reference in its entirety.

### BACKGROUND OF THE INVENTION

### 1. Field of the Disclosure

Example embodiments generally relate to electrically conductive fillers having corrosion resistance. In particular, example embodiments relate to nickel coated graphite (Ni/C) that is coated with nickel chromium (NiCr) which has a high resistance to oxidation and corrosion.

### 2. Background Information

During normal operation, electronic equipment generates undesirable electromagnetic energy that can interfere with the operation of proximately located electronic equipment due to electromagnetic interference (EMI). To minimize the problems associated with EMI, electrically conductive materials can be used to shield EMI. Conventional shields to reduce EMI can be constructed by conductive materials having silver coated powders (Ag/Cu, Ag/Al, Ag/glass) or Ni coated powders. These shields may be effective to reduce EMI, silver has limited corrosion resistance.

### SUMMARY

Example embodiments of the present disclosure relate to an electrically conductive composite powder for improving EMI shielding performance. In example embodiments, the electrically conductive composite powder includes a core of particles; a nickel layer coated onto the core of particles; and a corrosion resistant alloy layer that is deposited onto the nickel layer.

Preferred embodiments of the present disclosure relate to a nickel coated graphite (Ni/C) based electrically conductive filler in which a nickel coating layer is coated with nickel chromium (NiCr). In an example embodiment, the corrosion resistance of nickel is improved by adding chromium. In example embodiments, the nickel chromium (NiCr) layer exhibits a high resistance to oxidation and improves the corrosion properties of the Ni/C based electrically conductive filler.

In example embodiments, a powder of the Ni/C based electrically conductive filler may be produced with a density that is 30%. In an example embodiment, the Ni/C based electrically conductive filler includes a graphite core of particles, a nickel layer coated onto the graphite core of particles, and a nickel chromium (Ni/Cr) layer that is coated onto the nickel layer. In example embodiments, at least one layer of nickel, which acts as a corrosion resistant layer, can be added in the Ni/C based electrically conductive filler.

The Ni/C based electrically conductive filler of the present disclosure addresses problems, including high cost, of conventional Ag/glass shields.

### BRIEF DESCRIPTION OF THE DRAWINGS

The present disclosure is further described in the detailed description which follows, in reference to the noted plurality of drawings, by way of non-limiting examples of preferred embodiments of the present disclosure.

FIG. 1 illustrates a cross section of an electrically conductive filler, according to various embodiments.

### DETAILED DESCRIPTION

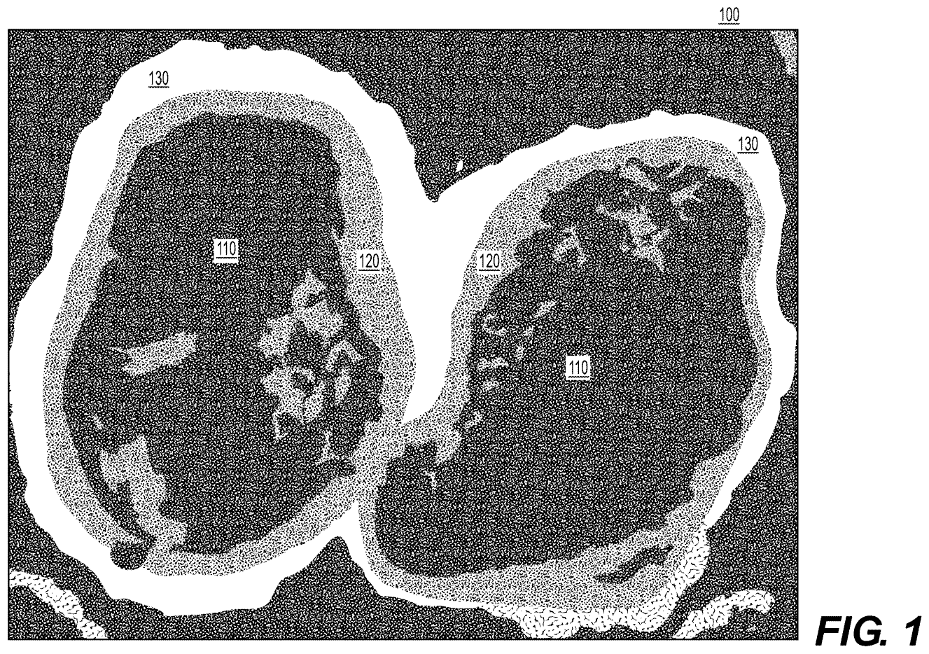

FIG. 1 illustrates a cross section of an electrically conductive filler 100, according to various embodiments. In FIG. 1, the electrically conductive filler 100 includes a core of particles 110, a nickel layer 120 coated onto the core of particles 110, and a corrosion resistant alloy layer 130 that is deposited onto the nickel layer 120. In embodiments, the electrically conductive filler 110 is embedded in a resin. In embodiments, Ni/Cu/C is loaded in silicon rubber in a 60/30 ratio by weight to produce conductive adhesives or extruded gaskets, which will provide shielding performance >100 db in the 40-100 GHz range.

In embodiments, the core of particles 110 is formed using a material having a low density, a high dielectric constant, and a low electrical resistance. Preferably, the core of particles 110 is formed using a material having a low density for the final composite particles to match the density of the resin. In one embodiment, the density of the material used for the core of particles 110 is 5 g/cm³ or less. In a preferred embodiment, the density of the material used for the core of particles 110 is less than 3 g/cm³. In a still preferred embodiment, the density of the material used for the core of particles 110 is less than 2.5 g/cm³. Some specific examples of materials suitable for the core of particles in this disclosure include, but are not limited, to graphite having a density of 2.266 g/cm³, silica having a density of 3.21 g/cm³, and titanium dioxide having a density of 4.23 g/cm³.

In embodiments, the core of particles 110 has a high dielectric constant of ≥10 which increases the shielding effectiveness of the core by enhancing the reflection of incident electromagnetic waves. The dielectric constant is a dimensionless property and defined as the ratio of the electric permeability of the material to the electric permeability in a vacuum. In one embodiment, the dielectric constant of the core of particles 110 is 2 or greater. In preferred embodiments, the dielectric constant of the core of particles 110 is 10 or greater. In still preferred embodiments, the dielectric constant of the core of particles 110 is 100 or greater. Exemplary examples of core of particles 110 include graphite having a dielectric constant of 10-15, titanium dioxide having a dielectric constant of 80-100, and silicon carbide having a dielectric constant of up to 10.

In embodiments, the core of particles 110 have a low electrical resistance by enhancing the adsorption of incident electromagnetic waves by the core material. In some embodiments, the core of particles 110 have an electrical resistivity at or below 10 Ohm*m. Graphite, titanium dioxide, and silicon carbide each has an electrical resistivity in the range of about 5×10⁻⁴ to 10 Ohm*m.

The electrically conductive filler 100 can be manufactured by coating the core of particles 110 having an average particle diameter (D50) of 0.05-100 μm with metallic nickel using, for example, plating, autoclave, or gas-phase technology. In embodiments, the coating core of particles 110 have an average particle diameter (D50) of 0.05-100 μm. In embodiments, the nickel layer 120 has a thickness of 0.1 to 4 μm. In embodiments, the nickel layer 120 has a preferable thickness of 1 to 2 μm.

The corrosion resistant alloy layer 130 is coated onto the nickel layer 120 via Physical Vapor Deposition (PVD), Metal-Organic Chemical Vapor Deposition (MOCVD), plating or autoclave methods. In another embodiment, the corrosion resistant alloy layer 130 is formed onto the nickel layer 120 by converting part of the nickel layer 120 into the corrosion resistant alloy layer 130.

In one embodiment, a relatively thin corrosion resistant alloy layer 130 is deposited onto the nickel layer 120 to further improve corrosion resistance. In embodiments, the corrosion resistant alloy layer 130 is deposited as the outer layer having a more noble galvanic potential in seawater than nickel as measured via ASTM G82. In some embodiments, the electrochemical potential of the corrosion resistant alloy layer 130 is −0.2 V as compared to Ag/AgCl reference or greater. In some embodiments, the electrochemical potential of the alloy is −0.1 V as compared to Ag/AgCl reference or greater.

Some non-limiting alloys of materials which can be used for the corrosion resistant layer 130 include, but are not limited to, Nickel-Chromium alloys and Nickel Copper alloys. Example embodiments of Nickel Copper alloys include Monels, Nickel 600 series alloys, stainless steels, and superalloys. Example embodiments of superalloys include Hastelloys, Inconels, and Tungsten. In embodiments the corrosion resistant layer 130 is formed via the pack diffusion process. In one embodiment, a nickel chromium layer is formed by chromium pack diffusion into the nickel layer 120. Similarly, a nickel copper layer can be formed with copper pack diffusion into the nickel layer 120. In one embodiment, the corrosion resistant layer 130 is a relatively thin nickel-chromium (NiCr) layer in a range of 100 nm to 500 nm that is formed via pack diffusion of chromium into the nickel layer 120.

In some embodiments, enhanced corrosion resistance is provided to the electrically conductive filler 100 without the use of known corrosion resistant elements which are expensive. In one embodiment the use of silver is specifically avoided. In another embodiment, gold is specifically avoided. In yet another embodiment, platinum is specifically avoided.

Further, at least because the invention is disclosed herein in a manner that enables one to make and use it, by virtue of the disclosure of particular exemplary embodiments, such as for simplicity or efficiency, for example, the invention can be practiced in the absence of any additional element or additional structure that is not specifically disclosed herein.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

1. An electrically conductive composite powder for improving EMI shielding performance, comprising:
a core of particles formed from a material having a low density of <5 g/cm³ and a high dielectric constant of ≥10;
a nickel layer coated onto the core of particles; and
a corrosion resistant alloy layer that is deposited onto the nickel layer.

2. The electrically conductive composite powder according to claim 1, wherein the corrosion resistant alloy layer has a galvanic potential of −0.2V in seawater as measured via ASTM G82.

3. The electrically conductive powder according to claim 1, wherein the corrosion resistant layer is applied via pack diffusion of an element or elements into the corrosion resistant layer.

4. The electrically conductive powder according to claim 1, wherein the corrosion resistant layer is applied via pack diffusion of chromium into the nickel layer.

5. The electrically conductive powder according to claim 1, wherein the corrosion resistant layer is a Nickel-Chromium alloy.

6. The electrically conductive powder according to claim 1, wherein the core of particles is at least one selected from the group consisting of graphite, titanium dioxide, and silicon carbide.

7. The electrically conductive powder according to claim 1, wherein the core of particles is graphite.

8. The electrically conductive powder according to claim 1, wherein the corrosion resistant layer has a thickness of 100 to 500 nm.

9. The electrically conductive powder according to claim 1, wherein said electrically conductive material does not include silver, gold, and/or platinum.

10. A nickel coated electrically conductive material for improving EMI shielding performance, comprising:
a core of particles;
a nickel layer coated onto the core of particles; and
a nickel chromium (Ni/Cr) layer that is deposited onto the nickel layer.

11. The nickel coated electrically conductive material according to claim 10, wherein the core of particles have an average particle diameter (D50) of 0.05-100 μm.

12. The nickel coated electrically conductive material according to claim 10, wherein the nickel layer has a thickness of 0.1 to 4 μm.

13. The nickel coated electrically conductive material according to claim 12, wherein the nickel layer has a thickness of 1 to 2 μm.

14. The nickel coated electrically conductive material according to claim 10, wherein the core of particles is at least one selected from the group consisting of graphite, titanium dioxide, and silicon carbide.

15. The nickel coated electrically conductive material according to claim 10, wherein the core of particles is graphite.

16. The electrically conductive material according to claim 10, wherein said electrically conductive material does not include silver, gold, and/or platinum.

17. A method for manufacturing an electrically conductive composite powder, comprising:
applying a nickel layer onto a core of particles comprising formed from a material having a low density of <5 g/cm3 and a high dielectric constant of ≥10; and
depositing a corrosion resistant alloy layer onto the nickel layer.

18. The method according to claim 17, wherein the corrosion resistant alloy layer comprises a material having a galvanic potential of >−0.2V in seawater as measured via ASTM G82.

19. The method according to claim 17, wherein the nickel layer is applied onto the core of particles by plating, autoclave, or gas-phase technology.

20. The method according to claim 17, wherein the corrosion resistant layer is deposited onto the nickel layer by plating, autoclave, or gas-phase technology.

21. The method according to claim 17, wherein the corrosion resistant layer is deposited onto the nickel layer by pack diffusion of an element or elements into the nickel layer.
